(19) United States
(12) Patent Application Publication
(10) Pub. No.: US 2010/0201385 A1
(43) Pub. Date: Aug. 12, 2010

(54) METHOD FOR MEASURING THE THRESHOLD THICKNESS OF A LAYER OF A PURELY RESISTIVE MATERIAL, DEVICE FOR IMPLEMENTING SAME AND USE OF SAID DEVICE IN AN EXHAUST PIPE

(75) Inventors: Francis Louis Menil, Saint Selve (FR); Claude Lucat, Cestas (FR); Pascal Tardy, Fargues Saint Hilaire (FR); Alexandrine Guedon, Mombrier (FR); Patrick Ginet, Bordeaux (FR)

Correspondence Address: OBLON, SPIVAK, MCCLELLAND MAIER & NEUSTADT, L.L.P., 1940 DUKE STREET, ALEXANDRIA, VA, 22314, US

(73) Assignees: CENTRE NATIONAL DE LA RECHERCHE SCIENTIFIQUE, Paris (FR); INSTITUT POLYTECHNIQUE DE BORDEAUX, Pessac Cedex (FR); UNIVERSITE DE BORDEAUX 1, Talence Cedex (FR)

(21) Appl. No.: 12/664,497

(22) PCT Filed: Jun. 12, 2008
(86) PCT No.: PCT/FR2008/000801

§ 371 Date: Apr. 22, 2010

(30) Foreign Application Priority Data
Jun. 13, 2007 (FR) 07 04221

(51) Int. Cl. G01R 27/08

(52) U.S. Cl. 324/700

(57) ABSTRACT

The invention provides a reliable, simple, and accurate method for detecting a threshold thickness of a purely-resistive material deposited on a sensor, and providing a response that is independent of the resistivity of the material. The invention provides a measurement method using a sensor comprising at least two electrode pairs having a defined voltage applied thereto generating current between the electrodes, the electrode pairs differing by at least one first parameter selected from the width, the spacing, and the length of the electrodes, and the voltage applied to each pair, and at least one second one of said parameters being adjusted so that a first resistance or a first current between the electrodes of the first pair, and a second resistance or a second current between the electrodes of the second pair are equal when the threshold thickness is reached.

The invention relates to a method of measuring a threshold thickness of a layer of purely-resistive material, the method being applicable in particular to deposits of soot in a motor vehicle exhaust. The invention also provides a device for implementing the method, and the use of such a device in an exhaust muffler.

The continuing lowering of the limits on polluting emissions from automobile exhausts, as imposed by national and international standards, constitutes a major constraint on automobile manufacturers. The 2005 European regulation Euro 4 accepts a maximum pollution rate of 0.025 milligrams per kilometer (mg/km), but future European regulation Euro 5, expected in 2010, will bring that threshold down to 0.005 mg/km, which means that particle filter (PF) technology will need to be implemented in all vehicles in all of the countries of the Union. That regulation is therefore going to increase present requirements significantly.

Improving PF control systems for better performance is thus a present priority for motor manufacturers. At present, no means are available on the market that enable the particle emissions of engines to be quantified with acceptable reliability. In certain vehicles, the operating cycles performed by the engine are stored and compared with a pre-recorded operating chart. PF regeneration is triggered on the basis of such comparisons. However, during the lifetime of an engine, the level of particle emission is likely to drift for any given operating cycle. The quantity of fuel may also modify emissions. These drifts are extremely difficult to incorporate. That system is therefore not very reliable and it is relatively expensive.

Another solution consists in taking account of head loss (pressure difference between the inlet and the outlet of the PF). Nevertheless, this back pressure is itself not exactly representative of the weight of the load in the filter, since it depends very strongly on the conditions under which soot has accumulated and on the nature of the soot, on the number of kilometers traveled by the vehicle, on the type of driving, etc.

Various techniques have been proposed for detecting particles of soot:
optical detection by light being diffused on the particles; that technique is difficult to use in engine applications because dust accumulates on the optical components and because of high costs, since the system needs to be capable of withstanding high temperatures;
electronic detection by modification to ionization current; that technique is likewise expensive since it requires high currents to be used; and
measuring a temperature rise as generated by combustion of the soot and proportional to the weight of the oxidized material (the principle of a catalytic sensor); that technique is less expensive, but is nevertheless difficult to apply to engines since the surrounding temperature is not only high, but it also fluctuates greatly.

There are well-known techniques for measuring the thickness of material by making capacitive measurements. Nevertheless, capacitive measurements can be envisaged only for materials that are essentially capacitive, i.e. in which resistance is negligible compared with capacitance, and they require a processor circuit that is complex. Such techniques are disclosed in documents U.S. Pat. No. 4,766,369 and U.S. Pat. No. 5,955,887 for detecting respectively a deposit of pure ice (a material that is purely capacitive) or a deposit of a mixture of water and ice (a mixture of materials for which the total impedance is measured).

For materials that are purely resistive, document WO 2005/124313 describes a method of influencing the deposition of soot on a sensor. That document deals with measuring the resistance of a deposit of purely-resistive material, and is based on the principle that in order to measure a resistance between the two electrodes of the sensor, a stage of forced minimum soot deposition is needed for the sensor to operate, i.e. to ensure that there is a finite resistance that can be measured. After this initial deposition, the resistance of the soot layer can be tracked as a function of the thickness of the deposit. It results that a threshold thickness can be detected only by comparing the measured resistance with a database of profiles for variation in resistance as a function of thickness. In addition to the lack of accuracy of such a method, the sensor must necessarily be associated with an electronic device that is complex and that is capable of performing a large amount of calculation. Furthermore, the technique described in that document presents the major drawback of measuring resistance in a manner that depends totally on deposition conditions, such as large fluctuations in temperature and in exhaust gas flow rate, and in the composition of the soot, which itself can fluctuate during the lifetime of an engine. Furthermore, the required stage of forced deposition of soot between the electrodes does not provide measurements that are representative of the deposition that takes place over the remainder of the surface while the exhaust muffler is in operation.

Thus, no technique that is simple and accurate has been proposed for detecting the deposition of a threshold thickness of a material that is purely resistive.

The present invention thus seeks to provide a method that is reliable, simple, and accurate for detecting the deposition of a threshold thickness of a material that is purely resistive, and that makes it possible to provide a response from the sensor that is independent of the resistivity of the material, of temperature, or of the flow rate of the exhaust gases.

To remedy the drawbacks of known techniques, the present invention provides a method of measuring a threshold thickness of a layer of purely-resistive material by making differential measurements of resistance between at least three electrodes forming at least two electrode pairs, in which the lengths and/or the widths and/or the applied voltages and/or the spacings are adjusted as a function of the deposit thickness to be measured.

To this end, the invention provides a method of measuring a threshold thickness of a layer of purely-resistive material deposited on a sensor, said sensor comprising at least three electrodes for defining at least two electrode pairs disposed in adjacent manner on a support and powered with a defined voltage generating a current between the electrodes, the electrode pairs differing by at least one first parameter selected from the width, the spacing, the length of the electrodes, and the voltage applied to each pair. In this method, at least one second parameter of said parameters is adjusted so that a first resistance or a first current between the electrodes of the first pair, and a second resistance or a second current between the electrodes of the second pair are equal when the threshold thickness is reached.

Because of its differential nature, the measurement is independent of experimental conditions such as temperature and the flow rate of the gas in which the layer is immersed. It is also independent of the resistivity of the deposit.

In other implementations:
the electrode pairs differ by at least one first parameter selected from the width and the spacing of each pair, and at least one second parameter selected from the spacing, the width, the length, and the voltage applied to the electrodes is adjusted so that a first resistance or a first current between the electrodes of the first pair and a second resistance or a second current between the electrodes of the second pair are equal when the threshold thickness is reached;
a width and/or a spacing of the first electrode pair is/are such that the derivative of the current between the electrodes of said first pair relative to the thickness of the layer tends towards zero as the thickness increases, and a width and/or a spacing of the second electrode pair is/are such that the current between the electrodes of the second pair increases substantially linearly with the thickness of the layer when the threshold thickness is reached, the method further comprising the steps consisting in:
   a) applying respective defined voltages to the pairs of electrodes;
   b) measuring a first resistance or a first current between the electrodes of the first pair;
   c) measuring a second resistance or a second current between the electrodes of the second pair;
   d) comparing the second and first resistances or the first and second currents; and
   e) generating a signal when said resistances or said currents are equal, the widths and/or the lengths, and/or the applied voltages, and/or the spacings of the electrodes being adapted so that said equality is obtained when the threshold thickness is reached;
the width of the electrodes of the first pair lies in the range 100 nanometers (nm) to 1 centimeters (cm), preferably in the range 10 micrometers (μm) to 1 millimeter (mm), typically in the range 30 μm to 250 μm, and the width of the electrodes of the second pair lies in the range 500 nm to 5 cm, preferably in the range 50 μm to 5 mm, typically in the range 250 μm to 1 mm;
the ratio between the width of the electrodes of the first pair and the width of the electrodes of the second pair lies in the range 1:1000 to 10:1, preferably in the range 1:100 to 1:1, typically in the range 1:10 to 1:2;
the spacing of the electrodes of the first pair lies in the range 100 nm to 1 cm, preferably in the range 10 μm to 1 mm, typically in the range 30 μm to 250 μm, and the spacing of the electrodes of the second pair lies in the range 500 nm to 5 cm, preferably in the range 50 μm to 5 mm, typically in the range 250 μm to 1 mm;
the ratio between the first and second spacings lies in the range 1:1000 to 1:1, preferably in the range 1:100 to 1:2, typically in the range 1:10 to 1:3;
the electrodes of the second pair present a length different from the length of the electrodes of the first pair;
the electrodes of the second pair have a voltage applied thereto that is different from the voltage applied to the electrodes of the first pair; and/or
the method may further comprise a step of cleaning the sensor by means of a heater resistance disposed on the support in such a manner as to ensure total combustion of the deposit of resistive material.

The invention also provides a method of dimensioning a detector device for detecting a threshold thickness of a layer of purely-resistive material deposited on electrodes of the device, in order to implement the above method. It comprises the following steps:
α) depositing a selected threshold thickness of purely-resistive material on first and second experimental electrode pairs that are connected to a voltage source, and that differ in a first parameter selected from the width and the spacing of the electrodes;
β) measuring the currents or the resistances at the selected threshold thickness for each experimental electrode pair, and calculating the ratio of the currents or the ratio of the resistances between the electrodes of each pair; and
γ) fabricating a sensor having two electrode pairs that differ by the same first parameter as the experimental electrodes and by at least one second parameter selected from the length and the voltage applied to the electrodes, the second parameter differing in a ratio equal to the ratio of the currents or to the ratio of the resistances as measured at the threshold thickness at preceding step β) between the experimental electrode pairs.

In other implementations:
during step α), the first and second experimental electrode pairs present respective first and second widths, but are of lengths, spacings, and applied voltages that are identical; and during step γ), a sensor is fabricated comprising two electrode pairs presenting respectively the same first and second widths as those of the experimental electrodes, and identical spacings, and in which the ratio between the lengths of the electrodes of the second and first pairs, or the ratio between the voltages applied in use to the terminals of the electrodes of the second and first pairs is equal to the ratio of the currents or of the resistances measured at the selected threshold thickness in prior step β) between the experimental electrode pairs;
during step α), the first and second experimental electrode pairs present respective first and second spacings, but are of lengths, widths, and applied voltages that are identical; and during step γ) a sensor is fabricated comprising two electrode pairs presenting respectively the same first and second spacings as the experimental electrodes, and identical widths, and in which the ratio between the lengths of the electrodes of the second and first pairs, or the ratio between the voltages applied in use to the terminals of the electrodes of the second and first pairs is equal to the ratio of the currents or of the resistances measured at the selected threshold thickness in prior step β) between the experimental electrode pairs; and/or
during step α), the first and second experimental electrode pairs differ by the width and the spacing of the electrodes, the electrodes being of lengths and applied voltages that are identical; and during step γ) a sensor is fabricated, comprising two pairs of electrodes presenting the same widths and spacings as the experimental electrodes, and in which the ratio between the lengths of the electrodes of the second and first pairs, or the ratio between the voltages applied in use to the terminals of the electrodes of the second and first pairs is equal to the ratio of the currents or of the resistances measured at the selected threshold thickness in prior step β) between the experimental electrode pairs.

The invention also provides a detector device for detecting a threshold thickness of a layer of purely-resistive material by implementing the above measurement method, the device comprising a sensor provided with at least three electrodes for defining at least two electrode pairs disposed in adjacent manner on a support, a voltage source connected to the electrodes and adjusted to deliver a voltage between each electrode pair, and measurement means for measuring the resistances or the currents between the electrode pairs. The device further comprises means for comparing the resistances or the currents with one another and means for generating a signal when the measured resistances or the measured currents are equal. The pairs of electrodes differ by at least one first parameter selected from the width and the spacing of the electrodes, and by at least one second parameter selected from the spacing, the width, the length, and the setting of the voltage source applied to the electrodes, the second parameter being such that, in use, equal resistances or currents are obtained when the threshold thickness that is to be detected has been deposited on the electrodes.

In other embodiments:
the width and/or a first spacing of the first pair of electrodes are such that, in use, the derivative of the current between the electrodes of said first pair relative to the thickness of the layer tends towards zero as the thickness increases, and a width and/or a second spacing of the second electrode pair are such that, in use, the current between the electrodes of the second pair increases substantially linearly with the thickness of the layer when the threshold thickness is reached, the width and/or the length and/or the spacings of the electrodes, and/or the setting of the voltage source being adapted so that equal resistances or currents are obtained when the threshold thickness is reached;
a mask of insulating material is placed on the electrodes so as to leave only a determined length of electrode in electrical contact with the layer of resistive material;
the electrodes are disposed in parallel, interdigitated, or combined manner;
the detector device may be obtained by the above dimensioning method, and may have two pairs of electrodes presenting respectively the same first and second widths as the experimental electrodes, identical spacings, and in which the ratio between the lengths of the electrodes of the second and first pairs, or the ratio between the voltages applied in use to the terminals of the electrodes of the second and first pairs is equal to the ratio of the currents or of the resistances measured at the selected threshold thickness in step β) of the dimensioning method, between the experimental electrode pairs;
the detector device may be obtained by the above dimensioning method, and may have two electrode pairs presenting respectively the same first and second spacings as the experimental electrodes, and identical widths, and in which the ratio between the lengths of the electrodes of the second and first pairs, or the ratio between the voltages applied in use to the terminals of the electrodes of the second and first pairs is equal to the ratio of the currents or of the resistances measured at the selected threshold thickness in step β) of the dimensioning method, between the experimental electrode pairs; and/or
the detector device may be obtained by the above dimensioning method, and may have two electrode pairs presenting the same widths and spacings as the experimental electrodes, and in which the ratio between the lengths of the electrodes of the second and first pairs, or the ratio between the voltages applied in use to the terminals of the electrodes of the second and first pairs is equal to the ratio of the currents or of the resistances measured at the selected threshold thickness in step β) of the above dimensioning method, between the experimental electrode pairs.

The invention also provides the use of the above measurement method for detecting the deposition of a threshold thickness of a layer of soot in an exhaust muffler. During said use, the signal generated in step e), when the first and second resistances or currents are equal, can serve to trigger a step of regenerating the particle filter.

Finally, the invention provides an exhaust muffler provided with a particle filter, including at least one above detector device located upstream from the particle filter for implementing the above measurement method. The exhaust muffler may also include at least one above detector device located downstream from the particle filter.

Other characteristics of the invention are set out in the detailed description below made with reference to the accompanying figures, in which:

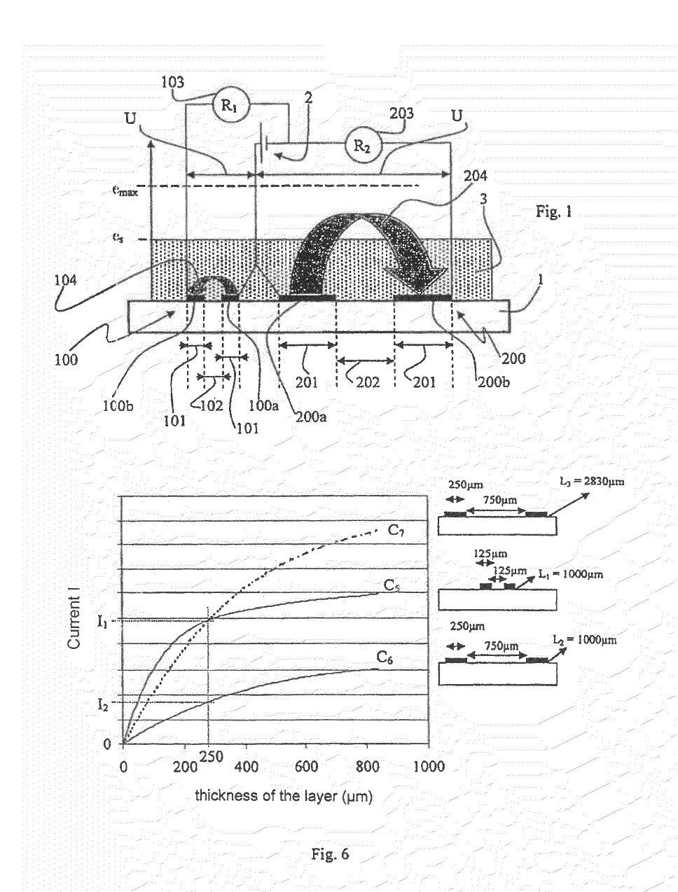

FIG. 1 is a diagrammatic section view of a detector device of the invention;

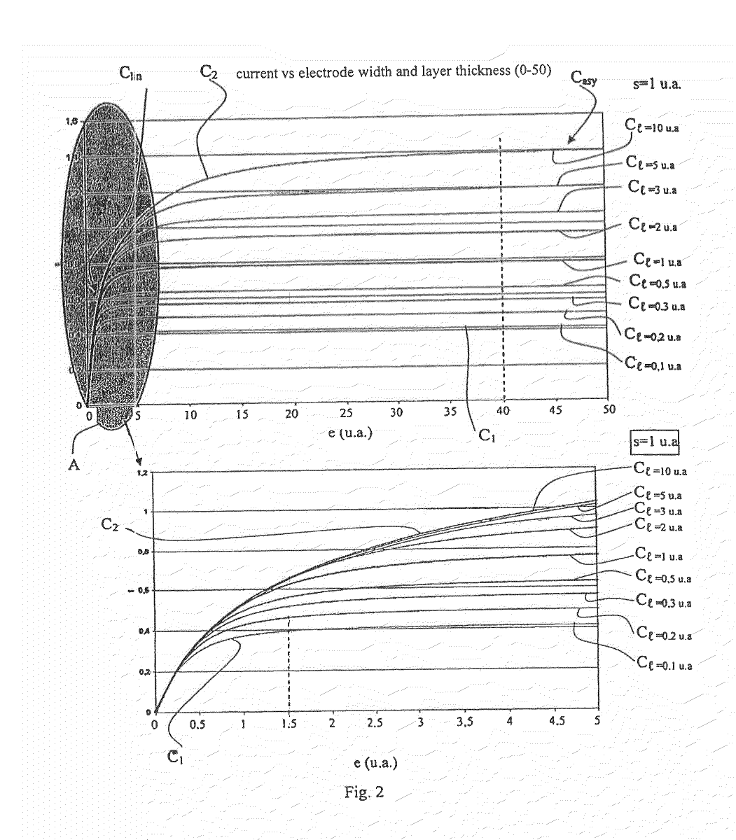

FIG. 2 is a general diagram and an enlargement of a detail A of the diagram, showing the influence of electrode width, at constant spacing, on variation in current between the electrodes as a function of the thickness of the deposit;

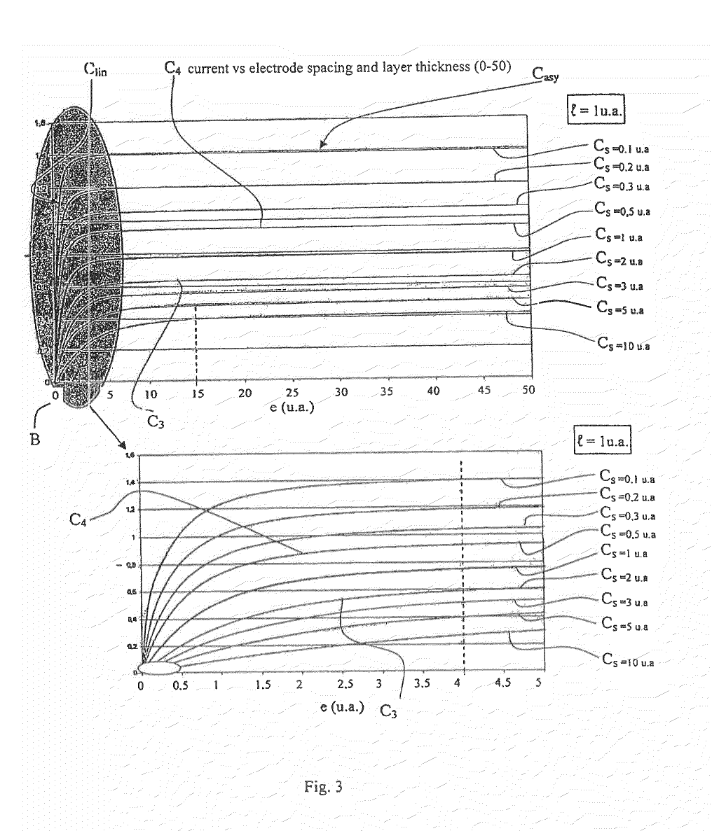

FIG. 3 is a general diagram together with an enlargement of a detail B of the diagram, showing the influence of electrode spacing, at constant width, on the variation in current between the electrodes as a function of the thickness of the deposit;

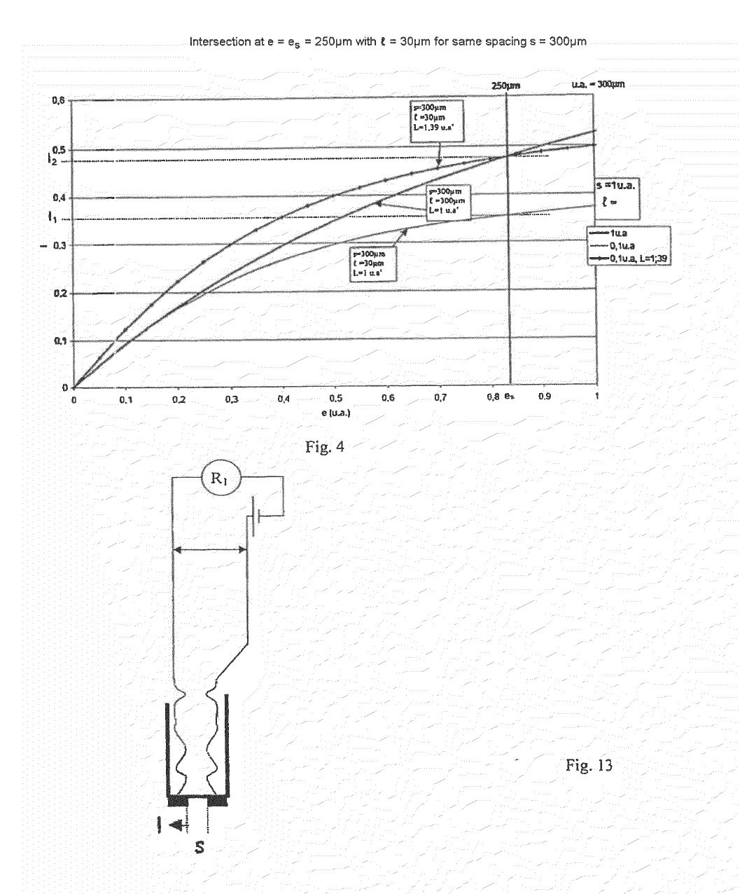

FIG. 4 is a diagram illustrative of an implementation of the method of the invention, consisting in using pairs of electrodes of different widths and identical spacing and adapting the length of one of the pairs as a function of the threshold thickness to be determined;

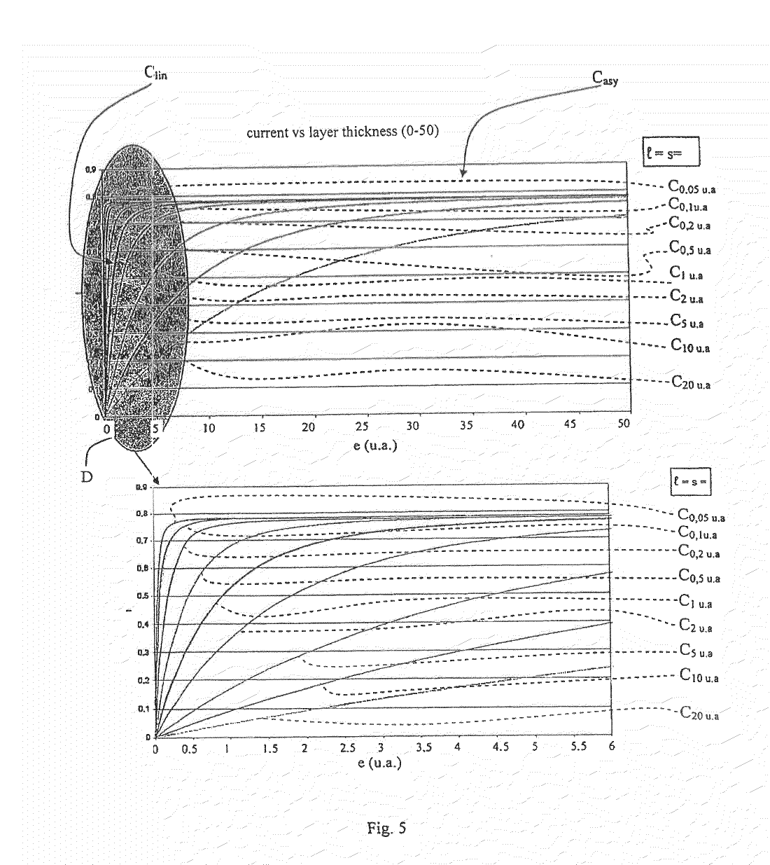

FIG. 5 is a general diagram together with an enlargement of a detail D of the diagram, showing the influence of the width and spacing values of the electrodes for a width/spacing ratio equal to 1, on the variation in the current as a function of the thickness of the deposit;

FIGS. 5a and 5b are diagrams illustrative of two implementations of the method of the invention, consisting in using pairs of electrodes of different widths and spacings but with a width/spacing ratio equal to 1, and in adapting the length of one of the pairs as a function of the threshold thickness to be determined;

FIG. 6 is a diagram showing how current varies between two electrodes of the device of the invention as a function of the thickness of the deposited layer of purely-resistive material;

FIGS. 7 and 8 are diagrammatic plan views of a sensor of the invention before and after dimensioning the electrodes;

FIGS. 9 to 12 are diagrammatic plan views of sensors of the invention presenting different electrode layouts; and

FIG. 13 is a diagrammatic section view of a device for implementing the method of the invention for direct measurement of the resistivities of a layer of material.

The method of the invention for measuring a threshold thickness of purely-resistive material proposes taking a differential measurement of resistance or of current in the layer of purely-resistive material between two pairs of electrodes placed on an insulating support. The term “two pairs of electrodes” should be understood in a functional rather than a structural sense, i.e. the measurements may be performed between two pairs of electrodes obtained with three physical electrodes, one of the electrodes belonging to both pairs of electrodes.

The method applies essentially to materials that are conductors or semiconductors of electrons, as contrasted with materials that are dielectric.

The pairs of electrodes are characterized by the height, the width, the length, and the spacing of the electrodes. Below, all of the electrodes are considered as having identical height that is negligible relative to the threshold thickness to be detected.

To obtain a differential measurement of resistance or of current, the width and/or the length and/or the voltages and/or the spacings are optimized relative to the threshold thickness of the layer that is to be determined.

Thus, a detector device of the invention comprises a sensor provided with at least three electrodes for defining at least two electrode pairs placed in adjacent manner on a medium. The device also includes a voltage source connected to the electrodes and adjusted to deliver an applied voltage between each electrode pair. The adjustment of the voltage source enables the electrode pairs to be fed with the same voltage or with different voltages.

The voltage generates a current between the electrodes of each pair when resistive material is deposited on the electrodes. The sensor also includes means for measuring resistances or currents between the electrode pairs, means for comparing the resistances or currents with one another, and means for generating a signal when the measured resistances or currents are equal. According to the invention, the electrode pairs differ in at least one first parameter selected from: the width and the spacing of the electrodes; and at least one second parameter selected from: the spacing, the width, the length, and the adjustment of the source of the voltage applied to the electrodes. The second parameter is such that, in use, resistance or current equality is obtained when the threshold thickness to be detected is deposited on the electrodes.

Thus, the diagram of FIG. 1 shows a device for detecting a threshold thickness of a purely-resistive material, the device comprising a sensor provided with two electrode pairs 100 and 200 presenting different widths 101, 201 and different spacings 102, 202, that are deposited in adjacent manner on a support 1. A terminal of one of the electrodes 100a, 200a in each pair 100, 200 is connected to a generator 2 that is adjusted to deliver a defined voltage U, and a terminal of the other electrode 100b, 200B in each pair 100, 200 is connected to respective resistance measurement means 103, 203. The measurement means may be an ohmmeter or an ammeter serving to measure the magnitude of the current flowing between the electrodes, with resistance then being obtained by Ohm's law. The device also includes comparator means (not shown) for comparing the resistances or currents with each other, and generator means (not shown) for generating a signal when the measured resistances or currents are equal.

The widths 101, 201 and/or the spacings 102, 202 are selected so that: firstly the electric field lines 104 that result from applying a voltage between the two electrodes 100a, 100b of the first electrode pair 100 remain for the most part confined inside the layer 3 of purely-resistive material; and secondly so that at least some of the electric field lines 204 that result from applying a voltage between the electrodes 200a, 200b of the second pair 200 remain outside the material layer 3 when the thickness of said layer reaches the threshold thickness eₛ that is to be detected.

Thus, so long as some of the electric field lines remain outside the material layer 3, current increases substantially linearly with the thickness of the layer. This variation is illustrated by the curves of FIGS. 2, 3, and 5 in the substantially linear portion Cₗᵢₙ of each curve.

However, as the thickness of the deposit increases so that the electric field lines between two electrodes remain confined for the most part inside the material layer, the derivative dI/de of the current relative to the thickness tends towards zero. This variation is illustrated in FIGS. 2, 3, and 5 by the asymptotic portion C_{asy} of each curve.

It suffices to vary only one of the electrode width and spacing parameters to obtain curves that present distinct appearances representative of the fact that the first electrode pair develops the asymptotic character before the second pair.

Preferably, in order to obtain results that are accurate while limiting the size of the electrodes and the quantity of material used, the variation of said parameter is selected so that firstly the first electrode pair reaches saturation before the threshold thickness has been deposited, i.e. that the electric field lines that result from applying a voltage between the two electrodes remain for the most part confined inside the layer of purely-resistive material, and secondly so that the second pair of electrodes reaches saturation after the deposit reaches the threshold thickness, i.e. at least some of the electric field lines that result from applying a voltage between the electrodes remain outside the material layer when the thickness of said layer reaches the threshold thickness Eₛ to be detected.

Thus, FIG. 2 shows the influence of the width “l” of the electrodes on the curve showing how current I varies between the electrodes as a function of the thickness e of the deposit. The width l, the spacing s, and the thickness e of the deposit are expressed using the same arbitrary unit (u.a). The length L, the spacing s, and the voltage U remain constant. FIG. 2, and the enlargement of detail A (graph at the bottom of FIG. 2) show that the smaller the width of the electrodes, the smaller thickness e at which saturation occurs. Thus, a pair having electrodes with a width of 0.1 u.a (curve C1 at the bottom of each graph) reaches its asymptotic current (about 0.4 u.a) at a thickness of about 1.5 u.a (enlargement of detail A), whereas a pair having electrodes of width 10 u.a (curve C2 at the top in each graph) reaches its asymptotic current (about 1.4 u.a) at a thickness of about 40 u.a.

FIG. 3 shows the influence of electrode spacing on the curve representing variation in current between the electrodes as a function of the thickness of the deposit. The width l, the spacing s, and the thickness e of the deposit are expressed in the same arbitrary unit (u.a). The length, the width, and the voltage remain constant. In FIG. 3, and the enlargement of detail B (bottom graph in FIG. 3) shows that the smaller the spacing between the electrodes, the smaller the thickness e at which saturation occurs. Thus, a pair having electrodes spaced apart by 10 u.a (bottom curve in each graph) reaches its asymptotic current (about 0.4 u.a) at a thickness of about 15 u.a, whereas a pair having its electrodes spaced apart by about 0.1 u.a (top curve in each graph) reaches its asymptotic current (about 1.4 u.a) at a thickness of about 4 u.a (enlargement of detail B).

These two figures show that by depositing two pairs of electrodes that differ in their width or their spacing, it is possible to dimension the electrodes so that the electric field lines that result from applying a voltage between the electrodes of the first pair remain confined to a greater extent within the layer of the purely-resistive material than do the field lines that result from applying a voltage between the electrodes of the second pair when the threshold thickness is reached. Nevertheless, the curves shown do not cross.

According to the invention, it is appropriate to vary at least two parameters during the stage of dimensioning the sensor, so that the curves representing the variation in the current between the electrode as a function of the thickness of the deposit cross at the threshold thickness that is to be detected. In other words, it is appropriate to select the following parameters: length; width; spacing; and applied voltage suitably so that the currents or resistances measured between each pair of electrodes are equal when the thickness of the deposited layer reaches the threshold thickness eₛ that is to be detected.

In a first implementation, the measurement method of the invention consists in adapting the length of the electrodes as a function of the threshold thickness to be determined, and more precisely in increasing the length of the electrode pair that is the more widely spaced apart or in increasing the voltage across the terminals of said pair, or indeed decreasing the length of the electrodes of the pair that is less spaced apart or in decreasing the voltage at the terminals of said pair, each time using a determined factor.

FIG. 4 shows this implementation as applied to the configuration described with reference to FIG. 2. Thus, two pairs of experimental electrodes present identical spacing of 1 u.a, but electrodes of different widths. In the example shown in FIG. 4, the first pair of electrodes presents a width l of 0.1 u.a and the second pair of electrodes presents a width l of 1 u.a. More precisely, the first pair presents electrodes having a width of 30 μm that are spaced apart by 300 μm and that have an arbitrary length of 1 u.a′ (where u.a′ is a unit length for electrode length, that is not necessarily equal to the unit length u.a used for the other dimensions, i.e. electrode width and spacing and also layer thickness). The second pair presents electrodes having a width of 300 μm, a spacing of 300 μm, and an arbitrary length of 1 u.a′.

Initially, the invention consists in calculating the ratio I₂/I₁ of the measured currents at the threshold thickness eₛ, here selected to be 250 μm, for each pair of electrodes. In FIG. 4, this ratio is equal to 1.39. The method of the invention then consists in multiplying the length of the electrodes in the first pair by this ratio so as to obtain a sensor suitable for implementing the measurement method of the invention. This causes the currents measured between these two pairs of electrodes as dimensioned in this way to be equal, and the device generates a signal indicative of the threshold thickness of material being deposited on the sensor.

In equivalent manner, instead of multiplying the length by the measured ratio, it is possible to multiply the voltage applied to the terminals of the first pair of electrodes.

Also equivalently, instead of multiplying the length or the applied voltage of the first pair by said ratio, it is possible to divide the length or the voltage applied to the second pair by said ratio.

The same procedure is applicable to the configuration described with reference to FIG. 3.

Nevertheless, it should be observed that in comparison with FIG. 2, greater latitude can be obtained in dimensioning the electrodes and thus greater accuracy can be obtained at the current crossover by acting on the electrode spacing rather than on electrode width, since with electrode width the curves are closer together in the non-asymptotic portion. In other words, the width of the electrodes has an influence that is smaller than the influence of the spacing between the electrodes in each pair.

In a second implementation, instead of adapting the length or the voltage, the measurement method of the invention consists in adapting the width or the spacing of the electrodes as a function of the threshold thickness to be determined.

In other words, when the pairs of experimental electrodes have electrodes of identical width and differ only in their spacing, the method in the second implementation consists in adapting only the width of the electrodes of the sensor so that the curves cross at the threshold thickness. Similarly, when the pairs of experimental electrodes have identical spacing and differ only in the width of the electrodes, then the method in the second implementation consists in adapting only the spacing of the sensor electrodes so that the curves cross at the threshold thickness.

Thus, the electrode pairs of the sensor differ only in the width and the spacing of the electrodes.

Nevertheless, as shown in FIG. 5 illustrating the situation when the ratio s/l is equal to one, it is impossible for the curves representing variations of current I as a function of the thickness e of the deposit to cross if both pairs present respective electrodes of width that is equal to the spacing s (e.g.: l=e=s=0.05 u.a for the first pair and l=s=2 u.a for the second pair), because all of the curves tend towards the same asymptote.

Thus, when the electrode pairs differ only in the width and the spacing of the electrodes, it is necessary for the two electrode pairs also to present different ratios s/l.

The dimensioning of the width and the spacing of the electrodes may be obtained by analytic simulation in a spreadsheet in order to plot the curve I=f(e).

To do this, the following notation is used:

k=tan h[πs/4e]/tan h[π(s+2l)/4e] [1]

k′=(1−k²)^{1/2} [2]

and

K(k)=(π/2){1+[(1/2)]²k²+[(1*3)/(2*4)]²k⁴+[(1*3*5)/(2*4*6)]²k⁶+ . . . } [3]

Then:

I=1/2K(k′)/K(k) [4]

A good approximation to I is given by the following equation:

I=(π/2){ln [2(1+k^{0.5})/(1−k^{0.5})]}⁻¹ for k²≧0.5 [5]

and

I=(1/2π)ln [2{1+(1−k²)^{0.25}}/{1−k²)^{0.25}}] for k²≦0.5 [6]

Then the curve I=f(e) is shown.

Thus, l and s are varied for different values of e. It is then possible to determine s and l pairs that enable the curves to cross at the selected threshold thickness.

### EXAMPLE 1

### Causing the Two Curves C1 and C2 of FIG. 2 to Cross by Modifying the Spacing of One of the Experimental Electrode Pairs

The object is to determine the spacing of the first experimental electrode pair, while conserving its width l₁=0.1 u.a and while keeping the second pair unchanged (s₂=1 u.a, l₂=10 u.a), so that the two currents intersect at eₛ=2 u.a.

The expression for the current in a medium of finite thickness e for coplanar experimental electrodes is given by the formulae [1] to [6].

For e=eₛ, the two currents need to be equal, which implies that k₁=k₂=kₛ. Applying formula [1] to the second pair of electrodes gives:

kₛ=k₂=tan h[π*1/(4*2)]/tan h[(π(1+2*10)/(4*2)]=0.374

Since k₁=kₛ, applying formula [1] to the first electrode pair gives:

tan h[π*s₁/(4*2)]=0.374*tan h[π(s₁+2*0.1)/(4*2)]

By putting both sides of the equality into a spreadsheet and incrementing s₁, current I is equal when s₁≈0.12.

### EXAMPLE 2

### Causing the Curves C3 and C4 of FIG. 3 to Cross by Modifying the Width of One of the Experimental Electrode Pairs

The object is to determine therewith l₁ of the first electrode pair, while conserving its spacing s₁=0.5 u.a and while keeping the second pair unchanged (s₂=2 u.a, l₂=1 u.a) so that the two currents intersect at eₛ=2 u.a.

A calculation analogous to that of Example 1 leads to the following for the second pair of electrodes:

kₛ=k₂=tan h[π*2/(4*2)]/tan h[π(2+2*1)/(4*2)]=0.715

Since k₁=kₛ, the following results for the first pair of electrodes:

tan h[π*0.5/(4*2)]=0.715*tan h[π(0.5+2*l₁)/(4*2)]

By entering both sides of the equality into a spreadsheet and incrementing l₁, current I is found to be equal when l₁≈0.105.

Varying the two parameters to cause the curves of each experimental electrode pair to cross at the selected threshold thickness may suffice for certain threshold thicknesses, but it is difficult or even impossible to implement for other threshold thickness values.

A preferred implementation of the invention, that is easier to implement, consists in varying at least three parameters. Thus, by initially varying two parameters (e.g. width l and spacing s), two curves are obtained that present appearances that are quite distinct, representative of the fact that the first electrode pair develops the asymptotic nature before the second pair. Thereafter, a third parameter is adapted (e.g. by increasing the length of the most-spaced electrode pair or the terminal voltage of said pair, or indeed by reducing the length of the electrodes of the less-spaced pair or reducing the voltage at the terminals of said pair) so that the curves cross precisely at the selected threshold thickness. This implementation makes it possible to avoid using dimensions for the two pairs of electrodes that differ excessively, since that is not always compatible with the technology used and/or the intended application. This makes it possible to improve overall detection accuracy. An example is shown in FIG. 6.

As explained above, the method of the invention for detecting a threshold thickness is based on varying the ratio I₁/I₂, and thus, if the applied voltages are identical, on varying the ratio of the two resistances R₂/R₁ with the thickness of the layer. In strictly equivalent manner, the differences I₁−I₂ or R₂−R₁ could equally well be measured.

Best results are obtained for spacing and/or width and/or length and/or voltage ranges in which the currents flowing between the first pair of electrodes, when the threshold thickness eₛ is reached, lies in the asymptotic domain of the curve C5, whereas the current flowing between the second pair of electrodes when the threshold thickness eₛ is reached, lies in the substantially linear domain of the curve C6. Nevertheless, when the spacing is equal to the width for each electrode pair (FIGS. 5, 5a, 5b), selecting s=l on either side of the threshold thickness is not essential, even though it is preferable.

In general, it is appropriate to select the dimensions for the electrode pairs that are relatively far apart so as to obtain an “angle” that is sufficiently large between the curves representing the two currents (more exactly the tangents to the curves) so as to obtain an accurate crossing.

In the implementation illustrated by FIG. 6, a method of the invention consists in adapting the lengths of the electrodes as a function of the threshold thickness to be detected and of the widths and the spacings of the electrodes.

The threshold thickness eₛ to be detected is 250 μm of resistive soot particles. The first experimental electrode pair presents electrodes of width 101 of 125 μm and a spacing 102 likewise equal to 125 μm. The second experimental electrode pair presents electrodes of width 201 of 250 μm and a spacing 202 likewise equal to 750 μm.

In this example, the two curves C5 and C6 represent experimental results for determining the dimensions of the electrodes of the second pair 200. This dimensioning stage is performed with two experimental electrode pairs on an insulating support. The thickness of all of the electrodes is set at 10 μm and their length at 1000 μm. These curves may also be obtained by analytic simulation using above-described equations [1] to [6] or by numerical simulation using finite elements.

Once the electrodes have been placed on the insulating support, the resistive material is deposited in successive layers and the current, and thus the resistance, is measured at the terminals of each electrode pair as a function of the total deposited thickness of material, up to a predetermined maximum total thickness eₘₐₓ (FIG. 1) that is greater than the threshold thickness that is to be detected.

Another solution consists in fabricating a resistive layer having a maximum total thickness eₘₐₓ of 850 μm by successive depositions of resistive material, either by silkscreen printing for small thicknesses, or by the so-called “Dr. Blade” method for larger thicknesses. Baking is performed at 850° C. after each deposition. The final resistive layer having a thickness of 850 μm is then thinned in stages using an abrasive disk and the two resistances R₁ and R₂ are measured after each thinning operation.

This dimensioning stage thus consists in following variation in the ratio I₁/I₂ or the ratio R₂/R₁ as a function of the thickness of the resistive layer. This ratio goes through the value 2.83 when the thickness of the layer reaches the threshold value eₛ of 250 μm that is to be detected.

The dimensioning method of the invention then consists either in multiplying the length of the electrodes of the second pair 200 by this factor of 2.83 determined at the threshold thickness eₛ, or in equivalent manner, in dividing the length of the electrodes of the first pair 100 by said factor. Multiplying the ordinates of curve C6 In FIG. 6 by this factor leads to curve C7. This curve, corresponding to electrodes that are wider and more spaced apart with a length of 2830 μm, and the curve C5 corresponding to the electrodes that are closer together with a length of 1000 μm, then intersect substantially at abscissa point eₛ=250 μm. The ratios I₁/I₂ or R₂/R₁ of the currents or the resistances between the electrodes of the pairs 100 and 200 as dimensioned in this way are equal to 1 when the thickness of the purely-resistive material reaches the threshold value eₛ, in this example of 250 μm. An alternative would be to measure the variation in the differences I₁−I₂ or R₂−R₁, these differences being zero when the thickness of purely-resistive material reaches the threshold value eₛ, in this example of 250 μm. This implementation optimizes the accuracy of the response of the sensor around the threshold thickness eₛ compared with the implementation in which only the width and the spacing are adjusted, so that the ratio I₁/I₂ is equal to 1 at the threshold value eₛ.

FIG. 5 is useful for dimensioning electrode pairs as a function of the threshold thickness that is to be detected.

It can be seen in FIG. 5 that the asymptotic behavior appears at a thickness that is smaller with smaller values of the ratio (s=l)/e. Preferably, the first electrode pair is selected to have a spacing that is less than at least five times the threshold thickness (curve s=l=1 u.a at abscissa 5 u.a, for example). The second electrode pair may be selected in such a manner as to be as far away as possible from the asymptotic region at 5 u.a. The curve s=l=10 u.a appears to be a good compromise for avoiding excessively increasing the width and the spacing of the second electrode pair compared with the first. This selection leads to the dimensions shown in FIG. 5a so that the currents cross at eₛ=250 μm, i.e. s=l=50 μm and L=1 u.a′ (where u.a′ is a unit length for electrode length that is not necessarily equal to the unit length u.a used for the other dimensions, i.e. the width and the spacing of the electrodes and the thickness of the layer) for the smaller electrodes, and s==500 μm and L=2.19 u.a′ for the larger electrodes. FIG. 5b shows that selecting eₛ to be greater than 5s for the smaller electrodes is not absolutely essential since selecting eₛ=2s still leads to acceptable accuracy for the currents crossing (FIG. 5b), with the advantage of making it possible to use 125 μm technology instead of 50 μm technology that is more difficult and expensive to implement.

The dimensioning of the electrodes that are closer together and/or narrower is determined a priori by technological constraints. As a result, for the purpose of increasing the asymptotic character, there is no point in considering electrodes of width that is smaller than their spacing. It is then appropriate to select a minimum spacing value and a minimum width value that are made possible by the technology, and preferably for them to present a ratio s/l=1 for the closer-together electrodes.

For the electrodes that are spaced further apart, the desired retarding of the asymptotic character relative to the threshold thickness may be further increased by reducing the ratio s/l (FIG. 2) and thus by increasing the width of the electrodes (for fixed spacing). Nevertheless, since electrode width has less influence than electrode spacing on retarding the asymptotic character, this option is not necessarily very advantageous, since it implies increasing the quantity of metal used and making a device that is bulkier.

For the same reasons, it may therefore be found to be more advantageous not to seek to retard the asymptotic character relative to the threshold thickness, but instead to decrease the width of the electrodes that are the most spaced apart, finding a compromise with the corresponding loss of accuracy for the currents crossing.

To summarize, an example of the method of dimensioning a detector device for detecting a threshold thickness eₛ in a layer 3 of purely-resistive material deposited on the electrodes of the device, comprises the following steps:

α) depositing a selected threshold thickness eₛ of purely-resistive material on first and second experimental electrode pairs 100, 200 that are connected to a source 2 of voltage U, and that differ in a first parameter selected from the width and the spacing of the electrodes;

β) measuring the currents or the resistances at the selected threshold thickness eₛ for each experimental electrode pair, and calculating the ratio I₁/I₂ of the currents I₁, I₂ or the ratio R₂/R₁ of the resistances R₂, R₁ between the electrodes of each pair; and

γ) fabricating a sensor having two electrode pairs that differ by the same first parameter as the experimental electrodes and by at least one second parameter selected from the length and the voltage applied to the electrodes, the second parameter differing in a ratio equal to the ratio I₁/I₂ of the currents or to the ratio R₂/R₁ of the resistances as measured at the threshold thickness eₛ at preceding step β) between the experimental electrode pairs.

In a first variant of this dimensioning method:
during step α), the first and second experimental electrode pairs 100, 200 present respective first and second widths 101, 201, but are of lengths, spacings, and applied voltages that are identical; and
during step γ), a sensor is fabricated comprising two electrode pairs presenting respectively the same first and second widths 101, 201 as those of the experimental electrodes, and identical spacings, and in which the ratio L₃/L₁ between the lengths L₃, L₁ of the electrodes 200a, 200b, 100a, 100b of the second and first pairs 200, 100, or the ratio U₂₀₀/U, U/U₁₀₀ between the voltages U, U₂₀₀, U₁₀₀ applied in use to the terminals of the electrodes 200a, 200b, 100a, 100b of the second and first pairs 200, 100 is equal to the ratio of the currents I₁/I₂ or of the resistances R₂/R₁ measured at the selected threshold thickness eₛ in prior step β) between the experimental electrode pairs.

This first variant thus enables a detector device to be made that has two electrode pairs presenting respectively the same first and second widths 101 and 201 as the widths of the experimental electrodes, and identical spacing. In this device, the ratio L₃/L₁ between the lengths L₃, L₁ of the electrodes 200a, 200b, 100a, 100b of the second and first pairs 200 and 100, or the ratio between the voltages applied in use to the terminals of the electrodes of the second and first pairs 200 and 100 is equal to the measured ratio of the currents I₁/I₂ or of the resistances R₂/R₁, at the threshold thickness eₛ selected at step β) of the preceding dimensioning method, between the experimental electrode pairs.

According to a second variant of the dimensioning method:
during step α), the first and second experimental electrode pairs 100, 200 present respective first and second spacings 101, 201, but are of lengths, widths, and applied voltages that are identical; and
during step γ) a sensor is fabricated comprising two electrode pairs presenting respectively the same first and second spacings 102, 202 as the experimental electrodes, and identical widths, and in which the ratio L₃/L₁ between the lengths L₃, L₁ of the electrodes 200a, 200b, 100a, 100b of the second and first pairs 200, 100, or the ratio U₂₀₀/U, U/U₁₀₀ between the voltages U, U₂₀₀, U₁₀₀ applied in use to the terminals of the electrodes 200a, 200b, 100a, 100b of the second and first pairs 200, 100 is equal to the ratio of the currents I₁/I₂ or of the resistances R₂/R₁ measured at the selected threshold thickness eₛ in prior step β) between the experimental electrode pairs.

This second variant thus enables a detector device to be made having two pairs of electrodes presenting respective first and second spacings 101 and 201 that are the same as those of the experimental electrodes, and identical widths. In this device, the ratio L₃/L₁ between the lengths L₃ and L₁ of the electrodes 200a, 200b, 100a, 100b of the second and first pairs 200 and 100, or the ratio between the voltages applied in use to the terminals of the electrodes of the second and first pairs 200 and 100, is equal to the ratio of the measured currents I₁/I₂ or resistances R₂/R₁, at the threshold thickness eₛ selected at step β) of the preceding dimensioning method, between the experimental electrode pairs.

In a third variant of the method:
during step α), the first and second experimental electrode pairs 100, 200 differ by the width and the spacing of the electrodes, the electrodes being of lengths and applied voltages U that are identical; and
during step γ) a sensor is fabricated, comprising two pairs of electrodes presenting the same widths and spacings as the experimental electrodes, and in which the ratio L₃/L₁ between the lengths L₃, L₁ of the electrodes 200a, 200b, 100a, 100b of the second and first pairs 200, 100, or the ratio U₂₀₀/U, U/U₁₀₀ between the voltages U, U₂₀₀, U₁₀₀ applied in use to the terminals of the electrodes 200a, 200b, 100a, 100b of the second and first pairs 200, 100 is equal to the ratio of the currents I₁/I₂ or of the resistances R₂/R₁ measured at the selected threshold thickness eₛ in prior step β) between the experimental electrode pairs.

This third variant thus enables a detector device to be made having two pairs of electrodes presenting the same widths and spacings as the experimental electrodes. In this device, the ratio L₃/L₁ between the lengths L₃ and L₁ of the electrodes 200a, 200b, 100a, 100b of the second and first pairs 200 and 100, or the ratio between the voltages applied in use to the terminals of the electrodes of the second and first pairs 200 and 100, is equal to the ratio of the currents I₁/I₂ or the resistances R₂/R₁ as measured at the threshold thickness eₛ selected at step β) of the preceding dimensioning method, between the experimental electrode pairs.

In the various embodiments described, the width 101 of the first electrode pair may be selected to lie in the range 100 nm (nanometers) to 1 cm (centimeter), and preferably in the range 10 μm (micrometers) to 1 mm (millimeter), typically in the range 30 μm to 250 μm. The width of the electrodes in the second pair may be selected to lie in the range 500 nm to 5 cm, preferably in the range 50 μm to 5 mm, typically in the range 250 μm to 1 mm.

More generally, the width 101 of the first pair may be selected to be less than or equal to eₛ/2, preferably lying in the range eₛ/10 to eₛ/4.

Preferably, the ratio between the width of the electrodes of the first pair and the width of the electrodes of the second pair may lie in the range 1:1000 to 10:1, preferably in the range 1:100 to 1:1, typically in the range 1:10 to 1:2.

Furthermore, the spacing of the electrodes of the first pair is selected to lie in the range 100 nm to 1 cm, preferably in the range 10 μm to 1 mm, typically in the range 30 μm to 250μ, and the spacing of the electrodes of the second pair lies in the range 500 nm to 5 cm, and preferably in the range 50 μm to 5 mm, typically in the range 250 μm to 1 mm.

Preferably, the ratio between the first and second spacings lies in the range 1:1000 to 1:1, preferably in the range 1:100 to 1:2, typically in the range 1:10 to 1:3.

The electrode material also has an influence on the accuracy with which resistivity is measured. Thus, the electrodes are preferably constituted of doped silicon, of platinum, of gold, of silver-palladium, or of metallic oxides when the utilization atmosphere is corrosive, as applies for example in an exhaust muffler in use. If the atmosphere makes it possible, the materials used could also be aluminum, copper, tin, etc. The electrodes may thus be made of a wide variety of materials, providing their electrical resistivity remains negligible relative to that of the layer of thickness that is to be measured. It is also appropriate to ensure that the electrical resistance of the electrodes is negligible relative to that of the layer of thickness that is to be measured.

The measurement is made more accurate by using more accurate methods for fabricating the sensor, e.g. for depositing the electrodes on the insulating support.

For example, silkscreen printing allows dimensioning to be accurate to within only 5% to 10%, in particular for the electrodes that are shorter and closer together. Better accuracy could thus be obtained by depositing the electrodes photolithographically on an alumina substrate.

An advantageous solution, shown in FIGS. 7 and 8, consists in depositing a first electrode pair 100 of predetermined length greater than the desired length (in the example shown: greater than 1000 μm), and then in depositing a second pair of electrodes 200 of predetermined length greater than the previously dimensioned length, i.e. greater than 2830 μm. Masks 305, 405, and 450 of insulating material are then deposited so as to leave the layer of resistive material in contact with only a length L₁ for the electrodes in the first pair that is equal to the desired length, here 1000 μm, and a length L₃ for the electrodes of the second pair that is equal to the length determined during the dimensioning stage, here 2830 μm, i.e. equal to L₂ (the length of the second experimental electrode pair of 1000 μm) multiplied by the value of the ratio I₁/I₂ or R₂/R₁ of the experimental electrodes at the threshold thickness.

The mask also makes it possible to simplify fabrication of electrodes having predefined lengths, by separating the measurement zones from the connection zones. The mask layer should be made of an electrically insulating layer that is chemically inert relative to the electrodes, to soot, and to exhaust gases at temperatures up to at least the temperatures used for regenerating a particle filter (i.e. about 800° C.).

The electrodes may be dimensioned as a function of the application. Best accuracy is obtained for a range of thicknesses in which the conductance of the small pair of electrodes as a function of the thickness of the layer lies in the asymptotic range of the curve (right-hand portion of curve C5 in FIG. 6), while the conductance of the large pair lies in the pseudo-linear range (left-hand portion of curve C6 in FIG. 6).

To achieve this, it might be thought that the small electrodes should be as close together as possible and the large electrodes as far apart as possible. Nevertheless, if the ratio between the spacings of the electrodes in the two pairs is too great, then the large electrode lengths needed for obtaining a crossing between the resistance or current curves at the threshold value eₛ would be too great (in the embodiment where the length is adjusted to an appropriate ratio). In addition to drawbacks of size, there would be a risk of losing accuracy.

Another implementation of the invention consists in multiplying the voltage U at the terminals of the second electrode pair 200 (or in equivalent manner in dividing the voltage at the terminals of the first pair 100) by the value of the ratio I₁/I₂ of the experimental electrodes at the threshold thickness, the experimental electrodes differing by at least one parameter such as electrode spacing or width.

In other words, during the dimensioning stage, the same voltage U is applied to the terminals of the two electrode pairs 100 and 200. However in this electrode, instead of multiplying (or dividing) the length of the electrodes, it is the voltage that is multiplied (or divided). Thus, the measurement method of the invention consists in applying either a voltage U to the terminals of the first pair 100 and a voltage U₂₀₀ to the terminals of the second pair, where U₂₀₀ is equal to U multiplied by the value of the ratio I₁/I₂ of the experimental electrodes at the threshold thickness, or applying a voltage U to the terminals of the second pair 200 and a voltage U₁₀₀ to the terminals of the first pair, where U₁₀₀ is equal to U divided by the value of the ratio I₁/I₂ of the experimental electrodes at the threshold thickness.

Another possibility consists in crossing the currents at the threshold thickness by applying a higher voltage to the large electrode pair (second pair), the ratio of these “experimental” voltages then determining the ratio of the lengths of said second pair if both pairs of electrodes are to have the same voltage applied to them in the final device, given that that is simpler to implement. Alternatively, the voltage at the terminals of the first pair is reduced, with the ratio of these “experimental” voltages then determining the extent to which the length of the first pair is reduced, e.g. using a mask (as described above).

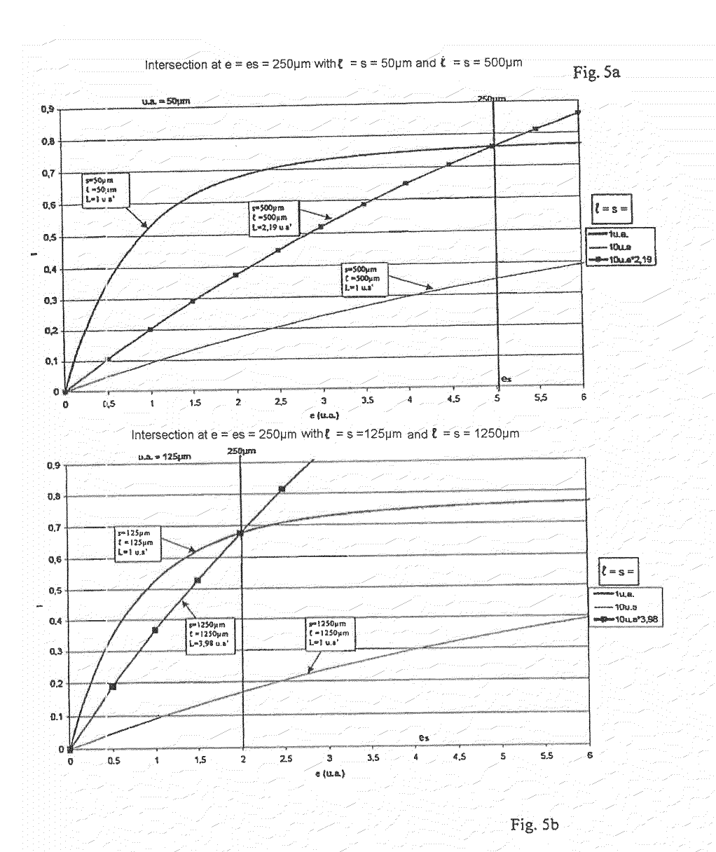

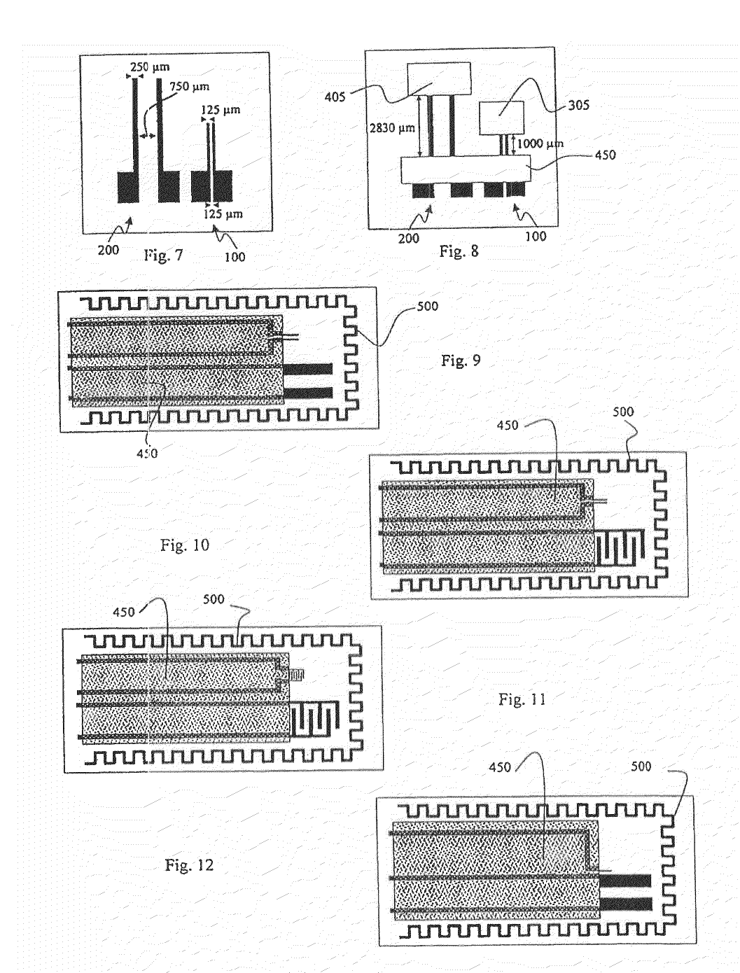

FIGS. 9 to 12 show various shapes and arrangements of electrode pairs. As shown in FIG. 9, both electrode pairs may be rectangular. To solve problems due to a large difference in length between the two electrode pairs, it is possible to envisage the electrodes of the first pair being rectangular and the electrodes of the second pair being interdigitated (FIG. 10). For layers that are highly resistive, it is possible to envisage using two pairs of interdigitated electrodes (FIG. 11). A design using three electrodes may also be envisaged (FIG. 12), providing the central electrode presents the same length and/or width as the length or width that was calculated during the dimensioning stage.

The sensors shown in FIGS. 8 to 12 also include a mask 450 of insulating material. The soot deposited between the connections must not significantly short-circuit the soot deposited between the electrodes. The above insulating layer serves to provide this protection all the way to wire connections with the electrical measurement circuit. These connections must be electronically insulated from the soot, or else they must be spaced far enough apart relative to the spacing between the electrodes.

One solution for doing without insulating masks, as described with reference to FIGS. 8 to 12, while nevertheless complying with the predefined shapes for the electrodes would be to provide the connections via the other face of the support by means of vias passing through the alumina under the electrodes.

In addition to enabling electrodes to be made to have the desired operating size, a solution using vias also makes it possible to make connections with the rear face of the alumina substrate. The problem of insulating and spacing the connections can thus possibly be simplified. Solutions with a multilayer alumina substrate having vias could also be envisaged as a way of solving isolation problems for the connections.

The measurement method and the detector device are suitable for use in detecting when a layer of soot particles has been deposited up to a threshold thickness in an exhaust muffler that includes a particle filter (PF) for the purpose of monitoring the PF and controlling regeneration thereof. For this purpose, the signal that is generated when the first and second resistances or currents are equal serves to trigger regeneration of the particle filter. For this purpose, at least one detector device of the invention is located upstream from the particle filter so as to implement the measurement method of the invention. This arrangement thus serves to determine when a threshold quantity of soot has formed at the filter particles.

Regeneration, which is performed at about 800° C., does not always suffice for eliminating all of the deposit of soot situated on the sensor of the detector device of the invention.

In order to clean the sensor and completely eliminate the deposit of soot situated on the electrodes, a heater resistance 500 is deposited on the medium so as to ensure total combustion of the deposit of resistive material.

The heater resistance is preferably made of platinum, however as for the electrodes, other conductive materials could be envisaged. The arrangement of the heater resistance 500 must ensure that temperature is distributed as uniformly as possible in the deposit of soot that covers the electrodes (FIGS. 9 to 12). The use of a differential circuit assumes that the deposit has the same resistivity at all locations on the surface covering the electrodes, and thus assumes that the temperature is the same for both electrode pairs.

The heater resistance may be placed either on the same side of the medium as the electrodes, around them (FIGS. 9 to 12), or else on the other face of the medium, under the electrodes. Technologies for depositing the heater resistance are the same as those described for depositing the electrodes.

The support needs to be selected so that:
it withstands the extremely difficult conditions of automobile exhausts, in particular great variations in temperatures (100° C. to 900° C.) and the corrosive nature of exhaust gases; and
it must be electrically and mechanically compatible with depositing electrodes and a heater resistance for ensuring combustion of the soot on the sensor, during PF regeneration sequences.

The plane substrates made of 96% to 99.9% alumina that are conventionally used for depositing thick or thin layers in hybrid microelectronics appear to be well suited. Nevertheless, it is possible to envisage using other insulating substrates, such as ceramics, glasses, silicon oxide, magnesium oxide, zirconium oxide, aluminum nitride, silicon nitride, boron nitride, etc. The support may be constituted either by an electrical insulator or by a conductor or a semiconductor that is coated in an electrical insulator. It may be constituted by a metal coated in an electrical insulator, zirconia, silicon carbide, etc. For applications in conditions that are not as hot and corrosive as in exhaust mufflers, the support may also be made of plastics material or of monocrystalline silicon.

The shape of the support is preferably plane, however it could be adapted as a function of utilization, for example it could be curvilinear or cylindrical in shape for use in an exhaust muffler, or indeed it may be in the shape of a glove finger.

The above-described sensors suitable for use in automobile exhaust may also be used in boilers, in particular fuel-oil boilers, or in chimneys. The advantage lies in optimizing the frequency with which boilers are cleaned and flues are swept.

The minimum thickness that can be measured is of the same order of magnitude as the width of the finer electrode. Using silicon technologies, it is thus possible to envisage measuring layer thicknesses starting from 0.1 μm. In certain applications, it is possible advantageously to replace a quartz balance for in situ monitoring of thickness while deposition is taking place.

The measurement method and the differential resistive sensor described in the present invention enable a threshold thickness of a purely-resistive material to be detected independently of its resistivity. They are applicable to determining the thickness of any purely-resistive material presenting finite electrical resistivity. Thus, the sensor is suitable for measuring a given threshold thickness over a wide range of resistivities without requiring recalibration as a function of the resistivity of the material and/or the conditions under which deposition and measurement take place (flow rate, temperature, and pressure of the exhaust gases).

The measurement method and the detector device of the invention are particularly suitable for determining a threshold thickness of a particulate deposit, in particular a deposit of soot particles having resistivity that may lie in the range 10″ ohm-centimeters (Ω.cm) to 10⁺⁸ Ωcm depending on the composition of the soot (in particular its hydrocarbon content) and the deposition temperature (temperature of the engine and of the exhaust gases influencing the composition of the deposit and its resistivity).

Furthermore, its low fabrication cost with materials that are tried and tested in automobile exhausts, the compatibility of its dimensions with those of the muffler, the simplicity and the reliability of its operation in conditions that are so hostile, all mean that the sensor is entirely suitable for satisfying the requirements of automobile manufacturers.

Numerous variants and alternatives may be provided without thereby going beyond the invention, and in particular:
the length L₁ of the electrodes 100a, 100b of the first pair may be shortened instead of lengthening the electrodes of the large pair. This reduction may be obtained by depositing an additional insulating mask; and
at least one detector device of the invention may also be located downstream from the particle filter.

The invention also applies to a method of measuring resistivity directly.

The asymptotic current obtained in FIG. 5 in a medium of finite thickness is practically equal to the current in a semi-infinite medium once the thickness of the material is greater than ten times the spacing between coplanar electrodes. When the width of the electrodes is identical to their spacing (s/l=1), then the asymptotic current is equal to 0.78 times the current per unit length that would be measured for the same resistive material sandwiched between two parallel electrodes of the same width and the same spacing as the coplanar electrodes.

Furthermore, if the length L of the coplanar electrodes is relatively long compared with their width and spacing (L more than about ten times greater than s=l), then the current is relatively insensitive to the length of the layer (perpendicular to the plane of the figures) once it is greater than the length of the electrodes.

Thus, by pressing the device with two coplanar electrodes or by placing two coplanar electrodes of spacing equal to their width and of length equal to about ten times their width on a resistive material of arbitrary shape, and applying a voltage while measuring the resistance between the electrodes, the resistivity of said material can be obtained directly, providing the thickness of the resistive material where contact is made therewith is at least five to ten times greater than the width of the electrodes.

The implementation device (ignoring direct deposition of coplanar electrodes on the material) could be constituted by a head provided with a pair of electrodes as shown in FIG. 13. By way of illustration, for electrodes having a width and a spacing of 500 μm, the length is about 5 mm, thereby giving relatively small dimensions to the measurement head. However it is possible to increase or decrease these dimensions as desired.

The measurement of resistance between the two electrodes then provides the resistivity of the material directly as follows:

ρ=0.78*R*L

where π is the resistivity, expressed in ohm-centimeters (Ω.cm), R is the resistance of the layer measured between the electrodes expressed in ohms (Ω), and L is the length of the electrodes, expressed in centimeters (cm).

The factor 0.78 is the asymptotic factor of FIG. 5.

Measurement accuracy is better than 1% if the thickness of the material is at least ten times the width of the electrodes, and better than 3% if said thickness is at least five times the width of the electrodes.

Accurate measurement requires good contact to be made between the electrodes and the material.

1. A method of measuring a threshold thickness (eₛ) of a layer (3) of purely-resistive material deposited on a sensor, said sensor comprising at least three electrodes (100a, 100b, 200a, 200b) for defining at least two electrode pairs (100, 200) disposed in adjacent manner on a support (1) and powered with a defined voltage (U, U₁₀₀, U₂₀₀) generating a current between the electrodes, the electrode pairs differing by at least one first parameter selected from the width, the spacing, the length of the electrodes, and the voltage applied to each pair, the method being characterized in that at least one second parameter of said parameters is adjusted so that a first resistance (R₁) or a first current (I₁) between the electrodes (100a, 100b) of the first pair (100), and a second resistance (R₂) or a second current (I₂) between the electrodes (200a, 200b) of the second pair (200) are equal when the threshold thickness (eₛ) is reached.

2. A measurement method according to claim 1, wherein the electrode pairs differ by at least one first parameter selected from the width and the spacing of each pair, and at least one second parameter selected from the spacing, the width, the length, and the voltage applied to the electrodes is adjusted so that a first resistance (R₁) or a first current (I₁) between the electrodes (100a, 100b) of the first pair (100) and a second resistance (R₂) or a second current (I₂) between the electrodes (200a, 200b) of the second pair (200) are equal when the threshold thickness (eₛ) is reached.

3. A measurement method according to claim 1 or claim 2, wherein a width (101) and/or a spacing (102) of the first electrode pair (100) is/are such that the derivative of the current between the electrodes (100a, 100b) of said first pair relative to the thickness of the layer (3) tends towards zero as the thickness increases, and a width (201) and/or a spacing (202) of the second electrode pair (200) is/are such that the current between the electrodes (200a, 200b) of the second pair increases substantially linearly with the thickness of the layer when the threshold thickness (eₛ) is reached, the method further comprising the steps consisting in:
a) applying respective defined voltages (U, U₁₀₀, U₂₀₀) to the pairs of electrodes (100, 200);
b) measuring a first resistance (R₁) or a first current (I₂) between the electrodes (100a, 100b) of the first pair (100);
c) measuring a second resistance (R₂) or a second current (I₂) between the electrodes (200a, 200b) of the second pair (200);
d) comparing the second and first resistances or the first and second currents; and
e) generating a signal when said resistances or said currents are equal, the widths (101, 201) and/or the lengths (L₁, L₂, L₃), and/or the applied voltages (U, U₁₀₀, U₂₀₀), and/or the spacings (102, 202) of the electrodes being adapted so that said equality is obtained when the threshold thickness (eₛ) is reached.

4. A method according to any one of claims 1 to 3, wherein the width (101) of the electrodes (100a, 100b) of the first pair (100) lies in the range 100 nm to 1 cm, preferably in the range 10 μm to 1 mm, typically in the range 30 μm to 250 μm, and the width (201) of the electrodes (200a, 200b) of the second pair (200) lies in the range 500 nm to 5 cm, preferably in the range 50 μm to 5 mm, typically in the range 250 μm to 1 mm.

5. A method according to claim 4, wherein the ratio between the width (101) of the electrodes of the first pair and the width (201) of the electrodes of the second pair lies in the range 1:1000 to 10:1, preferably in the range 1:100 to 1:1, typically in the range 1:10 to 1:2.

6. A method according to any one of claims 1 to 3, wherein the spacing (102) of the electrodes of the first pair lies in the range 100 nm to 1 cm, preferably in the range 10 μm to 1 mm, typically in the range 30 μm to 250 μm, and the spacing (202) of the electrodes of the second pair lies in the range 500 nm to 5 cm, preferably in the range 50 μm to 5 mm, typically in the range 250 μm to 1 mm.

7. A method according to claim 6, wherein the ratio between the first and second spacings (102, 202) lies in the range 1:1000 to 1:1, preferably in the range 1:100 to 1:2, typically in the range 1:10 to 1:3.

8. A method according to any one of claims 1 to 7, wherein the electrodes (200a, 200b) of the second pair (200) present a length (L₃) different from the length (L₁) of the electrodes (100a, 100b) of the first pair.

9. A method according to any one of claims 1 to 7, wherein the electrodes (200a, 200b) of the second pair (200) have a voltage (U₂₀₀) applied thereto that is different from the voltage (U₁₀₀) applied to the electrodes (100a, 100b) of the first pair.

10. A method according to any one of claims 1 to 9, further comprising a step of cleaning the sensor by means of a heater resistance (500) disposed on the support (1) in such a manner as to ensure total combustion of the deposit of resistive material.

11. A method of dimensioning a detector device for detecting a threshold thickness (eₛ) of a layer (3) of purely-resistive material deposited on electrodes of the device, in order to implement the method according to any one of claims 1 to 10, the dimensioning method being characterized in that it comprises the following steps:
α) depositing a selected threshold thickness (eₛ) of purely-resistive material on first and second experimental electrode pairs (100, 200) that are connected to a source (2) of voltage (U), and that differ in a first parameter selected from the width and the spacing of the electrodes;
β) measuring the currents or the resistances at the selected threshold thickness (eₛ) for each experimental electrode pair, and calculating the ratio (I₁/I₂) of the currents (I₁, I₂) or the ratio (R₂/R₁) of the resistances (R₂, R₁) between the electrodes of each pair; and
γ) fabricating a sensor having two electrode pairs that differ by the same first parameter as the experimental electrodes and by at least one second parameter selected from the length and the voltage applied to the electrodes, the second parameter differing in a ratio equal to the ratio (I₁/I₂) of the currents or to the ratio (R₂/R₁) of the resistances as measured at the threshold thickness (eₛ) at preceding step β) between the experimental electrode pairs.

12. A dimensioning method according to claim 11, wherein:
during step α), the first and second experimental electrode pairs (100, 200) present respective first and second widths (101, 201), but are of lengths, spacings, and applied voltages that are identical; and
during step γ), a sensor is fabricated comprising two electrode pairs presenting respectively the same first and second widths (101, 201) as those of the experimental electrodes, and identical spacings, and in which the ratio (L₃/L₁) between the lengths (L₃, L₁) of the electrodes (200a, 200b, 100a, 100b) of the second and first pairs (200, 100), or the ratio (U₂₀₀/U, U/U₁₀₀) between the voltages (U, U₂₀₀, U₁₀₀) applied in use to the terminals of the electrodes (200a, 200b, 100a, 100b) of the second and first pairs (200, 100) is equal to the ratio of the currents (I₁/I₂) or of the resistances (R₂/R₁) measured at the selected threshold thickness (eₛ) in prior step β) between the experimental electrode pairs.

13. A dimensioning method according to claim 11, wherein:
during step α), the first and second experimental electrode pairs (100, 200) present respective first and second spacings (101, 201), but are of lengths, widths, and applied voltages that are identical; and
during step γ) a sensor is fabricated comprising two electrode pairs presenting respectively the same first and second spacings (102, 202) as the experimental electrodes, and identical widths, and in which the ratio (L₃/L₁) between the lengths (L₃, L₁) of the electrodes (200a, 200b, 100a, 100b) of the second and first pairs (200, 100), or the ratio (U₂₀₀/U, U/U₁₀₀) between the voltages (U, U₂₀₀, U₁₀₀) applied in use to the terminals of the electrodes (200a, 200b, 100a, 100b) of the second and first pairs (200, 100) is equal to the ratio of the currents (I₁/I₂) or of the resistances (R₂/R₁) measured at the selected threshold thickness (eₛ) in prior step β) between the experimental electrode pairs.

14. A dimensioning method according to claim 11, wherein:
during step α), the first and second experimental electrode pairs (100, 200) differ by the width and the spacing of the electrodes, the electrodes being of lengths and applied voltages (U) that are identical; and
during step γ) a sensor is fabricated, comprising two pairs of electrodes presenting the same widths and spacings as the experimental electrodes, and in which the ratio (L₃/L₁) between the lengths (L₃, L₁) of the electrodes (200a, 200b, 100a, 100b) of the second and first pairs (200, 100), or the ratio (U₂₀₀/U, U/U₁₀₀) between the voltages (U, U₂₀₀, U₁₀₀) applied in use to the terminals of the electrodes (200a, 200b, 100a, 100b) of the second and first pairs (200, 100) is equal to the ratio of the currents (I₁/I₂) or of the resistances (R₂/R₁) measured at the selected threshold thickness (eₛ) in prior step β) between the experimental electrode pairs.

15. A detector device for detecting a threshold thickness (eₛ) of a layer (3) of purely-resistive material by implementing the measurement method according to any one of claims 1 to 10, the device comprising a sensor (10) provided with at least three electrodes (100a, 100b, 200a, 200b) for defining at least two electrode pairs (100, 200) disposed in adjacent manner on a support (1), a voltage source (2) connected to the electrodes (100a, 100b, 200a, 200b) and adjusted to deliver a voltage between each electrode pair, and measurement means (103, 203) for measuring the resistances (R₁, R₂) or the currents between the electrode pairs, the device being characterized in that it further comprises means for comparing the resistances or the currents with one another and means for generating a signal when the measured resistances or the measured currents are equal, and in that the pairs of electrodes differ by at least one first parameter selected from the width and the spacing of the electrodes, and by at least one second parameter selected from the spacing, the width, the length, and the setting of the voltage source applied to the electrodes, the second parameter being such that, in use, equal resistances or currents are obtained when the threshold thickness (eₛ) that is to be detected has been deposited on the electrodes.

16. A detector device according to claim 15, wherein the width (101) and/or a first spacing (102) of the first pair (100) of electrodes (100a, 100b) are such that, in use, the derivative of the current between the electrodes (100a, 100b) of said first pair relative to the thickness of the layer (3) tends towards zero as the thickness increases, and a width (201) and/or a second spacing (202) of the second electrode pair (200) are such that, in use, the current between the electrodes (200a, 200b) of the second pair increases substantially linearly with the thickness of the layer when the threshold thickness (eₛ) is reached, the width and/or the length and/or the spacings of the electrodes, and/or the setting of the voltage source being adapted so that equal resistances or currents are obtained when the threshold thickness (eₛ) is reached.

17. A detector device according to claim 15 or claim 16, wherein a mask (305, 405, 450) of insulating material is placed on the electrodes so as to leave only a determined length of electrode in electrical contact with the layer of resistive material.

18. A detector device according to any one of claims 15 to 17, wherein the electrodes are disposed in parallel, interdigitated, or combined manner.

19. A detector device according to claim 15, obtainable by the dimensioning method according to claim 12, the device having two pairs of electrodes presenting respectively the same first and second widths (101, 201) as the experimental electrodes, identical spacings, and in which the ratio (L₃/L₁) between the lengths (L₃, L₁) of the electrodes (200a, 200b, 100a, 100b) of the second and first pairs (200, 100), or the ratio (U₂₀₀/U, U/U₁₀₀) between the voltages (U, U₂₀₀, U₁₀₀) applied in use to the terminals of the electrodes (200a, 200b, 100a, 100b) of the second and first pairs (200, 100) is equal to the ratio of the currents (I₁/I₂) or of the resistances (R₂/R₁) measured at the selected threshold thickness (eₛ) in step β) of the dimensioning method according to claim 12, between the experimental electrode pairs.

20. A detector device according to claim 15, obtainable by the dimensioning method according to claim 13, the device having two electrode pairs presenting respectively the same first and second spacings (102, 202) as the experimental electrodes, and identical widths, and in which the ratio (L₃/L₁) between the lengths (L₃, L₁) of the electrodes (200a, 200b, 100a, 100b) of the second and first pairs (200, 100), or the ratio (Uₙₒ/U, U/U₁₀₀) between the voltages (U, U₂₀₀, U₁₀₀) applied in use to the terminals of the electrodes (200a, 200b, 100a, 100b) of the second and first pairs (200, 100) is equal to the ratio of the currents (I₁/I₂) or of the resistances (R₂/R₁) measured at the selected threshold thickness (eₛ) in step β) of the dimensioning method according to claim 13, between the experimental electrode pairs.

21. A detector device according to claim 18, obtainable by the dimensioning method according to claim 14, the device having two electrode pairs presenting the same widths and spacings as the experimental electrodes, and in which the ratio (L₃/L₁) between the lengths (L₃, L₁) of the electrodes (200a, 200b, 100a, 100b) of the second and first pairs (200, 100), or the ratio (U₂₀₀/U, U/U₁₀₀) between the voltages (U, U₂₀₀, U₁₀₀) applied in use to the terminals of the electrodes (200a, 200b, 100a, 100b) of the second and first pairs (200, 100) is equal to the ratio of the currents (I₁/I₂) or of the resistances (R₂/R₁) measured at the selected threshold thickness (eₛ) in step β) of the dimensioning method according to claim 14, between the experimental electrode pairs.

22. The use of the measurement method according to any one of claims 1 to 10 for detecting the deposition of a threshold thickness of a layer of soot in an exhaust muffler.

23. The use of the measurement method according to any one of claims 3 to 10 for detecting the deposition of a threshold thickness of a layer of soot in an exhaust muffler, during which method, the signal generated in step e), when the first and second resistances or currents are equal consists in triggering a step of regenerating a particle filter.

24. An exhaust muffler having a particle filter including at least one detector device according to any one of claims 15 to 21, located upstream from the particle filter in order to implement the measurement method according to any one of claims 1 to 10.

25. An exhaust muffler according to the preceding claim, further comprising at least one detector device according to any one of claims 15 to 21 located downstream from the particle filter.
